(19) United States
(12) Patent Application Publication
(10) Pub. No.: US 2026/0326194 A1
(43) Pub. Date: Oct. 22, 2026

(54) MOLYBDENUM CONTAINING POWDER AND TARGET

(71) Applicant: A.L.M.T. Corp., Tokyo (JP)

(72) Inventors: Yuri WATANABE, Toyama (JP); Makoto WATANABE, Toyama (JP); Yusuke OOTA, Toyama (JP); Yusuke YOSHINO, Toyama (JP)

(73) Assignee: A.L.M.T. Corp., Tokyo (JP)

(21) Appl. No.: 19/110,514

(22) PCT Filed: Oct. 3, 2024
(86) PCT No.: PCT/JP2024/035427

§ 371 Date: Mar. 11, 2025

(30) Foreign Application Priority Data
Oct. 12, 2023 (JP) 2023-176717

(51) Int. Cl. B22F 1/05; B22F 1/054; B22F 3/14; B22F 3/24; B22F 9/22; C23C 14/14; C23C 14/34; H01J 37/34

(52) U.S. Cl. CPC B22F 1/05; B22F 1/056; B22F 3/14; B22F 3/24; B22F 9/22; C23C 14/14; C23C 14/3414; H01J 37/3426; B22F 2003/247; B22F 2201/013; B22F 2301/20; B22F 2304/10; B22F 2998/10; B22F 2999/00; H01J 2237/332

(57) ABSTRACT

A molybdenum containing powder having an average particle size, as measured by a Fsss method, of 0.1 μm or more and 10 μm or less, containing 99.99% by mass or more of molybdenum, and having a compressive deformation strength of more than 0 MPa and 200 MPa or less.

### TECHNICAL FIELD

The present disclosure relates to molybdenum containing powder and a target. The present application claims priority to Japanese Patent Application No. 2023-176717 filed on Oct. 12, 2023. What is disclosed in the Japanese Patent Application is all incorporated herein by reference.

### BACKGROUND ART

Conventional molybdenum containing powders are disclosed, for example, in Japanese Patent Laying-Open No. 2005-133197 (PTL 1), Japanese Patent Laying-Open No. 2005-133198 (PTL 2), International Publication No. 2011-004887 (PTL 3), International Publication No. 2019-176962 (PTL 4), Japanese Patent Laying-Open No. 2005-314714 (PTL 5), and Japanese Patent Laying-Open No. 2005-314715 (PTL 6).

### CITATION LIST

### Patent Literature

PTL 1: Japanese Patent Laying-Open No. 2005-133197
PTL 2: Japanese Patent Laying-Open No. 2005-133198
PTL 3: International Publication No. 2011-004887
PTL 4: International Publication No. 2019-176962
PTL 5: Japanese Patent Laying-Open No. 2005-314714
PTL 6: Japanese Patent Laying-Open No. 2005-314715

### SUMMARY OF INVENTION

The presently disclosed molybdenum containing powder has an average particle size of 0.1 μm or more and 10 μm or less as measured by the Fsss method, contains 99.99% by mass or more of molybdenum, and has a compressive deformation strength of more than 0 MPa and 200 MPa or less.

### DESCRIPTION OF EMBODIMENTS

### Technical Problem to be Solved by the Present Disclosure

A sintered compact is produced from a conventional molybdenum containing powder. The sintered compact has a problem, that is, it is low in density.

### Description of Embodiments of the Present Disclosure

Initially, embodiments of the present disclosure will be listed and described.

### (Conventional Problem)

Conventionally, powder of ADM (ammonium molybdate) or MoO₃ (molybdenum trioxide) is introduced into a reduction boat, which is in turn inserted into a reduction furnace in an atmosphere of hydrogen and thus subjected to reduction at a determined temperature to produce an intermediate product. Further, the intermediate product is heated at an elevated temperature to produce molybdenum containing powder.

PTLs 1 and 2 disclose high purity metallic molybdenum coarse powder suitable for use as raw material powder to produce a high purity metallic molybdenum sintered target for sputtering.

PTL 3 discloses high purity molybdenum powder and a method for producing the same. Molybdenum has a purity of 99.99% or more and a ratio of 50% or more for primary particles. In the production method, ammonium molybdate salt powder is reduced with hydrogen. An aqueous solution of ammonium molybdate is brought into contact with cation exchange resin to prepare an aqueous solution comprising a molybdenum compound, which is in turn dried with a spray dryer. The obtained molybdenum oxide powder can be reduced to obtain powder containing molybdenum of high purity.

PTL 4 describes that a purity of 99.999% or more, a relative density of 98% or more, an average particle size of 45 μm or less, and a radiation dose of 0.03 cph/cm² or less allow less particles to be produced. Molybdenum powder is produced by hot pressing (HP).

In conventional art, when a molybdenum target for sputtering has pores therein, the target is not uniformly sputtered and microvoids are formed in a deposited film, and accordingly, it is necessary to provide a target having a low porosity and a high density. It has been desired to provide a molybdenum sputtering target capable of forming a molybdenum film having a low defect rate.

Generally, molybdenum is sintered at temperature of about 1800° C. to 2000° C., and in order to obtain a dense sintered compact, a heat treatment at an elevated temperature is essential.

Molybdenum containing powder having a W content of 90 ppm or more has a high compressive deformation strength as powder, and thus has large surface tension and hence low driving force for sintering and densification. Therefore, molybdenum containing powder is poor in sinterability and thus costly for sintering.

When molybdenum containing powder has a large volume diffusion coefficient, the powder has an enhanced driving force for sintering and densification. Less than 99.99% of molybdenum or a large W content results in a low volume diffusion coefficient due to inhibition by impurities or W. In other words, powder containing molybdenum of low purity is less likely to allow coarsening of crystal grains.

In view of this, there has been a demand for a powder containing molybdenum of high purity capable of densifying a sintered compact.

Using a molybdenum containing powder which is of high purity and low in compressive deformation strength, and sinterable and densifiable is expected to achieve the following effects:

First, using the powder can provide a molybdenum target having a low porosity and a high density and suppress formation of microvoids in a deposited film.

The powder can be sintered at low temperature, and hence at a reduced cost and also with less energy used, and thus be a solution for energy problems.

An EUV mask blank is coated with a multilayer film of Mo/Si, and as the film has irregularities of 1 nm therein, a phase shift of 50° or more will be caused for a wavelength of 13.5 nm, which may cause a defect. Using a high density molybdenum target made of powder containing molybdenum of high purity according to the present disclosure can contribute to reduction of defects otherwise caused during deposition of molybdenum.

### (Description of the Present Disclosure)

The presently disclosed molybdenum containing powder has an average particle size of 0.1 μm or more and 10 μm or less as measured by the Fsss method, contains 99.99% by mass or more of molybdenum, and has a compressive deformation strength of more than 0 MPa and 200 MPa or less.

The thus configured molybdenum containing powder that contains 99.99% by mass or more of molybdenum is easily reduced in compressive deformation strength. Molybdenum containing powder with compressive deformation strength of more than 200 MPa is less deformable, and tends to form pores when the powder is sintered.

Tungsten is treated as an impurity, and tungsten is not contained when 99.99% by mass or more of molybdenum is contained.

Molybdenum containing powder with an average particle size of less than 0.1 μm as measured by the Fsss method is flammable and difficult to handle. When molybdenum containing powder with an average particle size of more than 10 μm as measured by the Fsss method is used to produce a sintered compact, the sintered compact tends to be reduced in density. More preferably, the average particle size as measured by the Fsss method is 1 μm or more and 9 μm or less. This range allows safest handling, and also allows a sintered compact to have an increased density.

Preferably, the powder contains 90 ppm or less of tungsten. A ratio of tungsten contained that falls within this range ensures that the molybdenum containing powder has a reduced compressive deformation strength. More preferably, the powder has a tungsten content of 0 ppm or more and 10 ppm or less.

Preferably, the powder contains 99.999% by mass or more of molybdenum. A ratio of molybdenum contained that falls within this range ensures that the molybdenum containing powder has a reduced compressive deformation strength.

Preferably, the compressive deformation strength is more than 0 MPa and 135 MPa or less. In that case, small deformation strength ensures less pores while the powder is sintered.

Preferably, a target is produced from a sintered compact of the molybdenum containing powder, and sputtered to produce a mask blank having a surface with irregularities of less than 1 nm.

Preferably, a target is made of the molybdenum containing powder, and sputtered to form a thin film of molybdenum having 50 or less particles within 1 mm² of the thin film.

When conventional molybdenum containing powder is hot-pressed with a load of 50 MPa applied thereto, and thus sintered at a temperature of 1800° C. for 200 minutes, it has a sintered density of 93%, whereas the presently disclosed product has a sintered density of 98% or more. A high-density target having a low porosity can thus be provided.

Sintering at 1800° C. typically provides a relative density of 90% or more for a sintering time of 60 minutes, whereas sintering the presently disclosed product at 1800° C. for 60 minutes provides a relative density of 97.5% or more. This allows a reduced sintering cost.

### (Description of Production Method)

### (1) Refining

### Step 1

MoO₃ powder is introduced into a roasting furnace and has molybdenum sublimated therein at a temperature of 500° C. to 6500° C. The sublimate is caused to adhere to a lid of molybdenum and powder is collected to obtain MoO₃ powder having a low concentration of W. Repeating sublimation and rapid cooling at an appropriate temperature provides smaller W contents.

### (2) Reduction

### Step 2: Sieving Raw Material

A sieving mesh having a prescribed aperture is set for the refined MoO₃ powder and the raw material is passed therethrough for collection excluding coarse particles and fine powdery particles. The aperture of the sieving mesh is changed, as appropriate, depending on the raw material and the target particle size for the molybdenum powder.

Step 3: Reduction in First Stage (MoO₃→MoO₂)

The MoO₃ powder produced in Step 1 is sieved. Subsequently, the sieved powder is introduced into a molybdenum boat (containing 99.99% by mass or more of molybdenum). Optimal reducing conditions (temperature, a flow rate of hydrogen, an amount of raw material introduced, equipment used, etc.) are selected, as appropriate, so that the powder has a target particle size. The reduction in the first stage is thus performed.

### Step 4: Intermediate Sieving

The MoO₂ powder is sieved. This is done with a sieve, which has an aperture changed, as appropriate, depending on the raw material and the target particle size for the molybdenum powder.

### Step 5: Reduction in Second Stage (MoO₂→Mo)

The intermediately sieved MoO₂ powder is introduced into a molybdenum boat (containing 99.99% by mass or more of molybdenum). Reducing conditions are adjusted for a target Fsss particle size. The powder is reduced to be a powder containing metallic molybdenum, and thereafter removed from the boat.

### Step 6: Final Sieving

The obtained molybdenum containing powder is sieved. This is done with a sieve, which has an aperture changed, as appropriate, depending on the raw material and the target particle size for the molybdenum containing powder.

### Details of Embodiments of the Present Disclosure

### EXAMPLE

In an Example 1 of Sample No. 1 as below, Step 1: refining, Step 2: sieving raw material, Step 3: reduction in the first stage, Step 4: intermediate sieving, Step 5: reduction in the second stage, Step 6: final sieving, Step 7: sintering, Step 8: sputtering, and evaluation of thin film are performed.

### <Details of Process>

### Step 1: Refining

MoO₃ powder is heated and sublimed, and rapidly cooled to obtain a MoO₃ powder having a low concentration of W.

The powder is sublimed at a temperature preferably of 500° C. or higher and lower than 800° C.

Temperature lower than 500° C. does not facilitate sublimation of the MoO₃ powder. Temperature of 650° C. or higher increases sublimation of WO₃ powder, and it is difficult to obtain MoO₃ powder having a low content of W.

Repeating the sublimation and rapidly cooling step a plurality of times can provide a MoO₃ powder having a low content of W.

### Step 2: Sieving Raw Material

The MoO₃ powder refined in step 1 is sieved.

Step 3: Reduction in First Stage (MoO₃→MoO₂)

The MoO₃ sieved in step 2 is introduced into a molybdenum boat to a thickness of 35 mm. A pusher type reduction furnace is used to perform reduction treatment with hydrogen at a flow rate of 5 m³/h at a reduction temperature of 500° C. to obtain MoO₂.

The MoO₃ is preferably introduced into the boat to a thickness of 20 mm or more and 50 mm or less. When the thickness exceeds this range, reduction of the raw material in the boat may not proceed. Thickness below this range does work industrially (in terms of cost and efficiency).

The flow rate of hydrogen is preferably 3 m³/h or more. When the flow rate is less than 3 m³/h, reduction of the raw material in the boat may not proceed.

The reduction temperature is preferably 450° C. or higher and 650° C. or lower. When the reduction temperature exceeds 650° C., it is close to the melting point, and the raw material may melt. When the reduction temperature is lower than 450° C., reduction of the raw material in the boat may not proceed.

### Step 4: Intermediate Sieving

The MoO₂ obtained in Step 3 is sieved with an aperture of 1 mm. Coarse particles are removed and what is under the sieve is collected. The aperture is preferably 1 mm or less. When the aperture exceeds 1 mm, it cannot remove agglomerated powder, and reduction of remaining agglomerated powder may not proceed.

### Step 5: Reduction in Second Stage (Reduction of MoO₂)

The intermediately sieved MoO₂ powder is introduced into a molybdenum boat to a thickness of 20 mm. A pusher type reduction furnace is used to perform reduction treatment with hydrogen at a flow rate of 10 m³/h at a reduction temperature ranging from about 600 to 1260° C. in accordance with a target Fsss particle size. Reduction is performed until powder containing metallic molybdenum is obtained, and the thus obtained powder is removed.

The thickness is preferably 20 mm or more and 50 mm or less. When the thickness is more than 50 mm, reduction of the raw material in the boat may not proceed. Thickness less than 20 mm does not work industrially (in terms of cost and efficiency).

The flow rate of hydrogen is preferably 5 m³/h or more. When it is less than 5 m³/h, reduction of the raw material in the boat may not proceed.

The reduction temperature is preferably 600° C. or higher. When the reduction temperature is lower than 600° C., reduction of the raw material in the boat may not proceed.

### Step 6: Final Sieving

The obtained molybdenum containing powder is sieved using a sieve provided with a sieving mesh having an aperture of 500 μm or less to remove coarse agglomerated particles that tend to cause clogging. Powder under the sieve is thus collected.

### Step 7: Sintering

The powder obtained through Steps 1 to 6 was heated at a temperature of 1800° C. for 60 to 200 minutes with a pressure of 50 MPa applied thereto to produce a sintered compact of molybdenum. Further, a surface oxide was removed by machining to produce a high purity metallic molybdenum sintered target.

### Step 8: Sputtering

Of targets produced in Step 7, targets (sample Nos. 4, 7, 11, and 15) having a low W content and a relative density of 99% or more are brazed to a backing plate of pure copper. This was attached to a DC magnetron sputtering apparatus.

Sputtering was performed with a sputtering gas of Ar and a sputtering power of 300 W. A high purity metallic molybdenum thin film having a thickness of 0.3 μm was formed on the entire surface of a Si wafer having a diameter D of 100 mm.

### Sample Nos. 1 to 29 and Sample Nos. 101 to 104

How many times sublimation and cooling were performed was changed based on Sample No. 1. Sample Nos. 2 to 29 were thus produced. A result thereof is shown in Tables 1 and 2.

TABLE 1

| | | | | | | | relative | relative |
|---|---|---|---|---|---|---|---|---|
| | | | | | | frequency of | density | density |
| sample | | compressive | | | sublimation | sublimation & | for | for |
| nos. | Mo | strength | Fsss | W | temperature | cooling | 200 min | 60 min |
| 1 | 99.996 | 120 | 0.1 | 31 | 500 | 1 | 99.6 | 99.1 |
| 2 | 99.9978 | 118 | 0.2 | 13 | 500 | 2 | 99.7 | 99.2 |
| 3 | 99.9986 | 110 | 0.1 | 5 | 500 | 3 | 99.8 | 99.3 |
| 4 | 99.9991 | 102 | 0.2 | 0.1 | 500 | 5 | 99.92 | 99.42 |
| 5 | 99.9961 | 133 | 1 | 30 | 500 | 1 | 99.69 | 99.19 |
| 6 | 99.998 | 117 | 1 | 11 | 500 | 2 | 99.8 | 99.3 |
| 7 | 99.9991 | 100 | 1 | 0.1 | 500 | 5 | 99.93 | 99.43 |
| 8 | 99.9962 | 120 | 3.2 | 29 | 500 | 1 | 99.6 | 99.1 |
| 9 | 99.9978 | 118 | 3.3 | 13 | 500 | 2 | 99.7 | 99.2 |
| 10 | 99.9986 | 110 | 3 | 5 | 500 | 3 | 99.9 | 99.4 |
| 11 | 99.9991 | 101 | 3.1 | 0.1 | 500 | 5 | 99.94 | 99.44 |
| 12 | 99.996 | 120 | 4.8 | 31 | 500 | 1 | 99.7 | 99.2 |
| 13 | 99.9978 | 118 | 4.7 | 13 | 500 | 2 | 99.8 | 99.3 |
| 14 | 99.9986 | 110 | 4.9 | 5 | 500 | 3 | 99.85 | 99.35 |
| 15 | 99.9991 | 100 | 4.8 | 0.1 | 500 | 5 | 99.95 | 99.45 |
| 16 | 99.9964 | 124 | 9.3 | 27 | 500 | 1 | 98.5 | 98 |
| 17 | 99.9971 | 119 | 9.2 | 20 | 500 | 2 | 98.6 | 98.1 |
| 18 | 99.9984 | 113 | 9.2 | 7 | 500 | 3 | 98.7 | 98.2 |
| 19 | 99.9991 | 103 | 9.3 | 0.3 | 500 | 5 | 98.8 | 98.3 |
| 20 | 99.996 | 120 | 10 | 31 | 500 | 1 | 98.1 | 97.6 |

TABLE 2

| | | | | | | | relative | relative |
|---|---|---|---|---|---|---|---|---|
| | | | | | | frequency of | density | density |
| sample | | compressive | | | sublimation | sublimation & | for | for |
| nos. | Mo | strength | Fsss | W | temperature | cooling | 200 min | 60 min |
| 21 | 99.9979 | 118 | 9.9 | 12 | 500 | 2 | 98.2 | 97.7 |
| 22 | 99.9986 | 110 | 9.8 | 5 | 500 | 3 | 98.5 | 98 |
| 23 | 99.9991 | 100 | 10 | 0.1 | 500 | 4 | 98.7 | 98.2 |
| 24 | 99.9941 | 133 | 1 | 50 | 550 | 1 | 98.5 | 98 |
| 25 | 99.9942 | 125 | 9.4 | 49 | 550 | 1 | 98.4 | 97.9 |
| 26 | 99.9921 | 146 | 0.9 | 70 | 600 | 1 | 98.3 | 97.8 |
| 27 | 99.992 | 148 | 9.5 | 71 | 600 | 1 | 98.3 | 97.8 |
| 28 | 99.9901 | 160 | 1 | 90 | 650 | 1 | 98.1 | 97.6 |
| 29 | 99.9903 | 160 | 10 | 88 | 650 | 1 | 98.1 | 97.6 |
| 101 | 99.981 | 201 | 7.04 | 100 | | | 94 | 91.5 |
| 102 | 99.99 | 202 | 3 | 100 | | | 91 | 88.5 |
| 103 | 99.976 | 210 | 4.8 | 150 | | | 93.5 | 91 |
| 104 | 99.971 | 220 | 4 | 200 | | | 93 | 90.5 |

Sample No. 101 was produced according to PTL 1 (Japanese Patent Laying-Open No. 2005-133197). Sample No. 102 was produced according to PTL 3 (WO2011-004887).

In Tables 1 and 2, “Mo” indicates a ratio of molybdenum contained in molybdenum containing powder (in % by mass).

The ratio of molybdenum contained is analyzed through glow discharge mass spectrometry (GD-MS) using a flat cell. When glow discharge is performed in an atmosphere of Ar with a sample as a negative electrode, Ar gas collides with the sample to sputter constituent elements of the sample. The elements released by sputtering are ionized in a plasma of Ar. Ionized atoms are measured with a double-focusing mass spectrometer to calculate the elements' qualitativeness and concentration.

The ratio of molybdenum contained was calculated based on a formula of 100% minus 14 elements [Al, Ca, Cr, Cu, Fe, Mg, Mn, Ni, Pb, Si, Sn, Na, K, and W]. Tungsten (W) is treated as an impurity.

“Compressive strength” refers to strength as measured in a micro-compression test (for single granule crushing strength). The unit is “MPa”. The test was conducted with a micro compression tester MCT-510 produced by Shimadzu Corporation. A small amount of particles are spread on a sample stage. A single particle placed between an upper planar indenter and the lower, sample stage is subjected to a load increasing at a fixed rate. The sample deforms, and from this behavior, the particle's crushing strength is measured as its compressive deformation strength. As the sample deforms, testing force and compressive displacement are measured and recorded.

“Fsss” refers to an average particle size as measured by the Fsss method. The unit is “μm”. Fsss measurement is performed by the Fisher method. The measurement was performed using Fisher Sub-Sieve Sizer Model 95 of Fisher Scientific. A sample of a true density is introduced into a sample tube and voidage is determined from the sample's height, air having a pressure of 1 MPa is passed therethrough and a fluid level of a manometer is read as a numerical value on a calculator chart, and the value is represented as an average particle size in μm. Fsss represents powder's average particle size, and a smaller numerical value indicates a smaller average particle size.

“W” indicates a ratio (in ppm mass %) of tungsten contained in the molybdenum containing powder. Similarly as done to measure a ratio of molybdenum contained, a ratio of tungsten contained is analyzed through glow discharge mass spectrometry (GD-MS) using a flat cell. When glow discharge is performed in an atmosphere of Ar with a sample as a negative electrode, Ar gas collides with the sample to sputter constituent elements of the sample. The elements released by sputtering are ionized in a plasma of Ar. Ionized tungsten atoms are measured with a double-focusing mass spectrometer to calculate a ratio of tungsten contained.

“Sublimation temperature” refers to sublimation temperature in Step 1. The unit is “° C.”. Frequency of sublimation and cooling indicates how many times sublimation and cooling are performed in Step 1. A frequency of 1 indicates that sublimation was performed once and cooling was performed once.

“Relative density for 200 min” indicates a relative density of a sintered compact after sintering for 200 minutes in Step 7. “Relative density for 60 min” indicates a relative density of a sintered compact after sintering for 60 minutes in Step 7. Sintered compacts are measured in density by Archimedean principle.

From these results, Sample Nos. 1 to 29 are molybdenum containing powder having small compressive strength. As a result, a sintered compact produced from this powder is high in relative density.

On the other hand, Sample Nos. 101 to 104 as comparative examples are molybdenum containing powder having large compressive strength. As a result, a sintered compact produced from this powder is small in relative density.

Subsequently, Step 7 was followed to produce molybdenum targets from the sintered compacts of Sample Nos. 4, 7, 11, 15, 101, 103 and 104. The targets were sputtered to form thin film of molybdenum on a wafer. The number of particles present in an area of 1 mm square (1 mm×1 mm) of the thin film of molybdenum and having a maximum diameter of 0.1 μm or more was counted with a scanning electron microscope JSM-6460LA (produced by JEOL). This measurement was performed at five locations on a single wafer, and an average value of the five locations was determined. The result thereof is shown in Table 3.

TABLE 3

| sample | | compressive | | | |
|---|---|---|---|---|---|
| nos. | Mo | strength | Fsss | W | no. of particles |
| 4 | 99.9991 | 102 | 0.2 | 0.1 | 25 |
| 7 | 99.9991 | 100 | 1 | 0.1 | 28 |
| 11 | 99.9991 | 101 | 3.1 | 0.1 | 38 |
| 15 | 99.9991 | 100 | 4.8 | 0.1 | 49 |
| 101 | 99.981 | 201 | 7.04 | 100 | 100 |
| 103 | 99.976 | 210 | 4.8 | 150 | 120 |
| 104 | 99.971 | 220 | 4 | 200 | 180 |

From Table 3, it can be seen that thin films of molybdenum produced by sputtering the targets produced from Sample Nos. 4, 7, 11, and 15 each have a small number of particles and hence a favorable result. On the other hand, Sample Nos. 101, 103 and 104 as comparative examples each provide a large number of particles, and it can be seen that they provide targets of low quality.

Further, the targets produced from Sample Nos. 4, 7, 11, and 15 were sputtered to produce mask blanks of a multilayer film composed of a film of molybdenum and silicon deposited in layers. It has been confirmed that these mask blanks have a surface with irregularities of less than 1 nm. The irregularities of the surface of each mask blank were measured with an atomic force microscope (AFM). The irregularities of the surface of the mask blank were detected by moving a probe having a nanometer size close to the sample to detect an interatomic force acting between the probe tip and the sample.

### Additional Note 1

A molybdenum containing powder having an average particle size, as measured by a Fsss method, of 0.1 μm or more and 10 μm or less, containing 99.99% by mass or more of molybdenum, and having a compressive deformation strength of more than 0 MPa and 200 MPa or less.

### Additional Note 2

The molybdenum containing powder according to additional note 1, containing 90 ppm or less of tungsten.

### Additional Note 3

The molybdenum containing powder according to additional note 1 or 2, containing 99.999% by mass or more of molybdenum.

### Additional Note 4

The molybdenum containing powder according to any one of additional notes 1 to 3, wherein the compressive deformation strength is more than 0 MPa and 135 MPa or less.

### Additional Note 5

The molybdenum containing powder according to any one of additional notes 1 to 4, wherein a target is produced from a sintered compact of the molybdenum containing powder, and the target is sputtered to produce a mask blank having a surface with irregularities of less than 1 nm.

### Additional Note 6

A target formed of a sintered compact of the molybdenum containing powder according to any one of additional notes 1 to 5, the target being sputtered to deposit a thin film of molybdenum having on an area of 1 mm² thereof 50 or less particles having a maximum diameter of 0.1 μm or more.

It should be understood that the embodiments and examples disclosed herein are illustrative and non-restrictive in any respect. The scope of the present invention is defined by the terms of the claims rather than by the foregoing description, and is intended to encompass any modification falling within the meaning and range equivalent to the terms of the claims.

1. A molybdenum containing powder having an average particle size, as measured by a Fsss method, of 0.1 μm or more and 10 μm or less, containing 99.99% by mass or more of molybdenum, and having a compressive deformation strength of more than 0 MPa and 200 MPa or less.

2. The molybdenum containing powder according to claim 1, containing 90 ppm or less of tungsten.

3. The molybdenum containing powder according to claim 1, containing 99.999% by mass or more of molybdenum.

4. The molybdenum containing powder according to claim 1, wherein the compressive deformation strength is more than 0 MPa and 135 MPa or less.

5. The molybdenum containing powder according to claim 1, wherein a target is produced from a sintered compact of the molybdenum containing powder according to claim 1, and the target is sputtered to produce a mask blank having irregularities of less than 1 nm in height.

6. A target formed of a sintered compact of the molybdenum containing powder according to claim 1, the target being sputtered to deposit a thin film of molybdenum having on an area of 1 mm² thereof 50 or less particles having a maximum diameter of 0.1 μm or more.
